(19) United States
(12) Patent Application Publication
(10) Pub. No.: US 2025/0331186 A1
(43) Pub. Date: Oct. 23, 2025

(54) SEMICONDUCTOR MEMORY DEVICE AND MANUFACTURING METHOD OF THE SEMICONDUCTOR MEMORY DEVICE

(71) Applicant: SK hynix Inc., Icheon-si Gyeonggi-do (KR)

(72) Inventor: Dae Sung EOM, Icheon-si Gyeonggi-do (KR)

(73) Assignee: SK hynix Inc., Icheon-si Gyeonggi-do (KR)

(21) Appl. No.: 18/928,473

(22) Filed: Oct. 28, 2024

(30) Foreign Application Priority Data
Apr. 23, 2024 (KR) 10-2024-0054125

(51) Int. Cl. H10B 43/40; H10B 41/27; H10B 41/35; H10B 41/41; H10B 43/27; H10B 43/35

(52) U.S. Cl. CPC H10B 43/40; H10B 41/27; H10B 41/35; H10B 41/41; H10B 43/27; H10B 43/35

(57) ABSTRACT

A semiconductor memory device and a method of manufacturing the semiconductor memory device are provided. The semiconductor memory device includes a first insulating layer including a cell region and an extension region, a channel structure penetrating the first insulating layer in the cell region, a memory layer extending along a side wall of the channel structure, conductive layers disposed to be spaced apart in the vertical direction along a side wall of the memory layer over the first insulating layer, an active pattern coupled to a corresponding conductive layer among the conductive layers, and a gate electrode disposed over the active pattern.

### CROSS-REFERENCE TO RELATED APPLICATION

The present application claims priority under 35 U.S.C. § 119 (a) to Korean patent application number 10-2024-0054125 filed on Apr. 23, 2024, in the Korean Intellectual Property Office, the entire contents of which application is incorporated herein by reference.

### BACKGROUND

### 1. Technical Field

Various embodiments of the present disclosure generally relate to a semiconductor memory device and a manufacturing method of the semiconductor memory device, and more particularly, to a three-dimensional semiconductor memory device and a method of manufacturing the three-dimensional semiconductor memory device.

### 2. Related Art

A semiconductor memory device may be applied not only to small-sized electronic devices but also to electronic devices in various fields such as automobiles, medical care, and data centers. Accordingly, an increasing demand for semiconductor memory devices exists.

A semiconductor memory device includes a memory cell for storing data. A three-dimensional semiconductor memory device is more advantageous for achieving mass storage than a two-dimensional semiconductor memory device because the three-dimensional semiconductor memory device includes a plurality of memory cells arranged in three dimensions.

The degree of integration of memory cells in the three-dimensional semiconductor device may be improved by increasing the number of stacked memory cells. When the number of stacked memory cells is increased, the number of stacked conductive layers coupled to the memory cells may also be increased. As the number of stacked conductive layers is increased, a connection structure between a peripheral circuit controlling an operation of the memory cells and the conductive layers may become more complex and the operational reliability of the semiconductor memory device may deteriorate.

### SUMMARY

According to an embodiment, a semiconductor memory device may include a first insulating layer including a cell region and an extension region, a channel structure penetrating the first insulating layer in the cell region, a memory layer extending along a side wall of the channel structure, conductive layers disposed to be spaced apart in the vertical direction along a side wall of the memory layer over the first insulating layer, second insulating layers alternately disposed with the conductive layers in the vertical direction and extended over the extension region of the first insulating layer, an active pattern disposed between adjacent second insulating layers in the vertical direction among the second insulating layers and coupled to a corresponding conductive layer among the conductive layers, and a gate electrode disposed over the active pattern.

According to an embodiment, a semiconductor memory device may include a first insulating layer including a cell region and an extension region, a channel structure penetrating the first insulating layer in the cell region, a memory layer extending along a side wall of the channel structure, conductive layers and second insulating layers disposed over the first insulating layer and alternately stacked along a side wall of the memory layer, active patterns respectively extended from the conductive layers and disposed in a stepped structure over the extension region of the first insulating layer, and gate electrodes respectively disposed over the active patterns.

According to an embodiment, a method of manufacturing a semiconductor memory device may include forming a first insulating layer including a cell region and an extension region, stacking sub-structures over the first insulating layer, wherein each of the sub-structures is a stacked structure of a sacrificial layer and a second insulating layer, forming a stepped structure and a preliminary gate electrode by etching the sub-structures, wherein the stepped structure is disposed over the extension region of the first insulating layer and the preliminary gate electrode is disposed over the stepped structure and includes a portion of the sacrificial layer, forming a third insulating layer over the sub-structures to cover the stepped structure and the preliminary gate electrode, forming a first opening and a second opening overlapping the stepped structure, respectively, at both sides of the preliminary gate electrode and penetrating the third insulating layer, replacing a portion of the sacrificial layer of the stepped structure with an active pattern through the first opening and the second opening, replacing the sacrificial layer with a conductive material, and forming a first contact plug and a second contact plug in the first opening and the second opening, respectively.

### BRIEF DESCRIPTION OF THE DRAWINGS

FIG. 1 is a block diagram illustrating a semiconductor memory device according to an embodiment of the present disclosure;

FIG. 2 is a circuit diagram illustrating a memory cell array and a pass circuit according to an embodiment of the present disclosure;

FIG. 3 is a diagram illustrating a gate stack structure of a memory cell array according to an embodiment of the present disclosure;

FIG. 4A and FIG. 4B are cross-sectional views illustrating a semiconductor memory device according to an embodiment of the present disclosure;

FIG. 5 is a cross-sectional view illustrating a pass transistor according to an embodiment of the present disclosure;

FIGS. 6A, 6B, 6C, and FIG. 6D, FIGS. 7A, 7B, and 7C, FIGS. 8A, 8B, and 8C, and FIGS. 9A, 9B, 9C, and FIG. 9D are diagrams illustrating a manufacturing method of a semiconductor memory device according to an embodiment of the present disclosure; and

FIG. 10 is a block diagram illustrating an electronic system according to an embodiment of the present disclosure.

### DETAILED DESCRIPTION

Specific structural or functional descriptions disclosed herein are merely illustrative for the purpose of describing embodiments according to the concept of the present disclosure. Embodiments according to the concept of the present disclosure may be implemented in various forms and should not be construed as being limited to the specific embodiments set forth herein. Terms such as “first” and “second” are used to distinguish between various elements and do not imply size, order, priority, quantity, or importance of the elements. For example, a first element may be named as a second element in one example, and the second element may be named as a first element in another example. Terms such as “vertical,” “horizontal,” “over,” “side,” “lower,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

Various embodiments relate to a semiconductor memory device capable of improving the operational reliability and a method of manufacturing the semiconductor memory device.

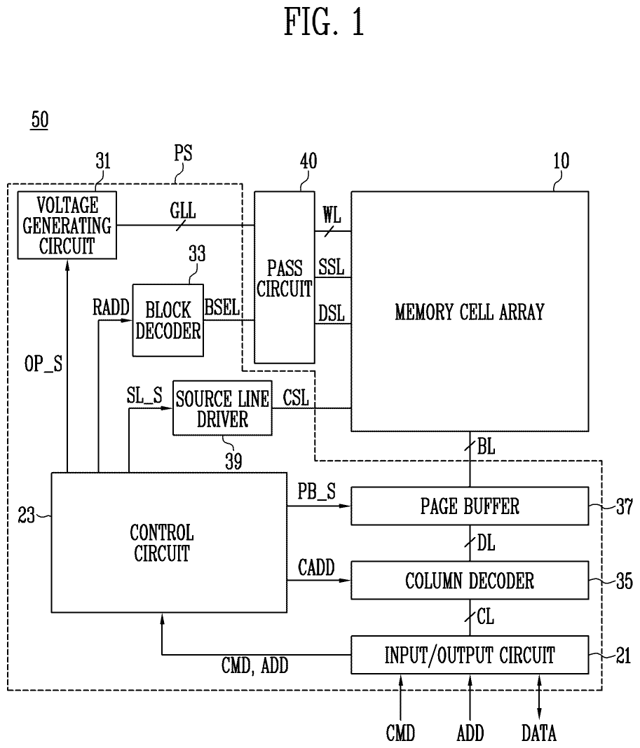

FIG. 1 is a block diagram illustrating a semiconductor memory device 50 according to an embodiment of the present disclosure.

Referring to FIG. 1, the semiconductor memory device 50 includes a memory cell array 10, a pass circuit 40, and a peripheral circuit structure PS.

The memory cell array 10 includes a plurality of memory blocks. Each of the memory blocks includes a plurality of memory cells. Each of the memory cells may be a non-volatile memory cell. In an embodiment, each of the memory cells may be a NAND flash memory cell. An embodiment of the present disclosure will be described below based on the semiconductor memory device 50 including the NAND flash memory cell, but the present disclosure is not limited thereto. In another embodiment, each memory cell may include a ferroelectric memory cell, a variable resistance memory cell, or the like.

The pass circuit 40 is connected to the memory cell array 10 via a word line WL, a source select line SSL, and a drain select line DSL.

The peripheral circuit structure PS is configured to perform a program operation that stores data in the memory cell array 10, a read operation that outputs data stored in the memory cell array 10, and an erase operation that erases data stored in the memory cell array 10. In an embodiment, the peripheral circuit structure PS may include an input/output circuit 21, a control circuit 23, a voltage generating circuit 31, a block decoder 33, a column decoder 35, a page buffer 37, and a source line driver 39.

The input/output circuit 21 transfers a command CMD and an address ADD, which are received from an external device (for example, a memory controller) of the semiconductor memory device 50, to the control circuit 23. The input/output circuit 21 exchanges data DATA with the external device and the column decoder 35.

The control circuit 23 outputs an operation signal OP_S, a row address RADD, a source line control signal SL_S, a page buffer control signal PB_S, and a column address CADD in response to the command CMD and the address ADD.

The voltage generating circuit 31 generates and output various operating voltages used for a program operation, a read operation, or an erase operation in response to the operation signal OP_S. The operating voltages output from the voltage generating circuit 31 are transferred to the pass circuit 40 via a plurality of global lines GLL.

The block decoder 33 outputs a block select signal in response to the row address RADD. The block select signal output from the block decoder 33 is transferred to the pass circuit 40 via a block select line BSEL.

The pass circuit 40 transfers the operating voltages that are transferred to the plurality of global lines GLL to the drain select line DSL, the word line WL, and the source select line SSL in response to the block select signal that is transferred to the block select line BSEL.

The column decoder 35 transfers the data DATA input from the input/output circuit 21 to the page buffer 37 or transfers the data DATA stored in the page buffer 37 to the input/output circuit 21 in response to the column address CADD. The column decoder 35 exchanges the data DATA with the input/output circuit 21 through a column line CL. In addition, the column decoder 35 exchanges the data DATA with the page buffer 37 through a data line DL.

The page buffer 37 stores read data received through a bit line BL in response to the page buffer control signal PB_S. The page buffer 37 senses a voltage or current of the bit line BL during a read operation. The page buffer 37 is connected to the memory cell array 10 through the bit line BL.

The source line driver 39 controls a voltage applied to a common source line CSL in response to the source line control signal SL_S. The source line driver 39 is connected to the memory cell array 10 through the common source line CSL.

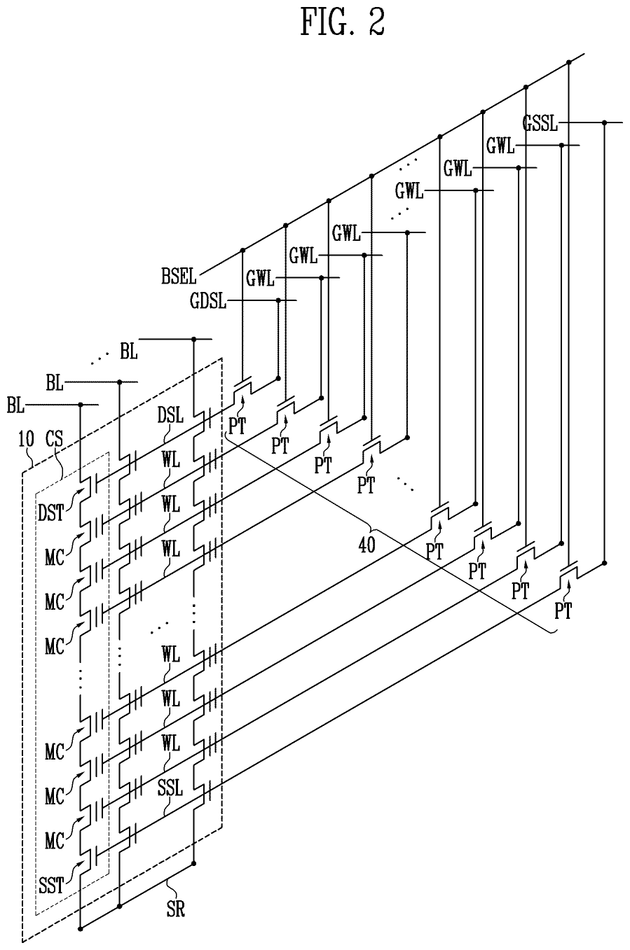

FIG. 2 is a circuit diagram illustrating the memory cell array 10 and the pass circuit 40 according to an embodiment of the present disclosure.

Referring to FIG. 2, the memory cell array 10 includes a plurality of memory cell strings CS. The plurality of memory cell strings CS are connected to a plurality of bit lines BL and a source layer SR. The plurality of memory cell strings CS are connected to the common source line CSL shown in FIG. 1 via the source layer SR.

Each of the memory cell strings CS includes at least one source select transistor SST, a plurality of memory cells MC, and at least one drain select transistor DST.

The source select transistor SST controls an electrical connection between the plurality of memory cells MC and the source layer SR. The drain select transistor DST controls an electrical connection between the plurality of memory cells MC and the bit line BL.

One source select transistor SST or at least two source select transistors SST coupled in series may be disposed between the source layer SR and the plurality of memory cells MC. One drain select transistor DST or at least two drain select transistors DST coupled in series may be disposed between each bit line BL and a plurality of memory cells MC in a corresponding memory cell string CS.

A plurality of gates of the plurality of memory cells MC are respectively coupled to a plurality of word lines WL. A gate of the source select transistor SST is coupled to the source select line SSL. A gate of the drain select transistor DST is coupled to the drain select line DSL.

The source select line SSL, the drain select line DSL, and the plurality of word lines WL are connected to the pass circuit 40. The pass circuit 40 includes pass transistor groups, and each pass transistor group includes a plurality of pass transistors PT connected to the same block select line BSEL. The plurality of pass transistors PT are connected to the source select line SSL, the drain select line DSL, and the plurality of word lines WL in a one-to-one manner.

The plurality of pass transistors PT transfer voltages that are applied to the plurality of global lines GLL to the source select line SSL, the drain select line DSL, and the plurality of word lines WL in response to the block select signal that is applied to the block select line BSEL. The plurality of global lines GLL include a global source select line GSSL, a global drain select line GDSL, and a plurality of global word lines GWL respectively corresponding to the source select line SSL, the drain select line DSL, and the plurality of word lines WL.

Conductive layers of a gate stack structure serve as the source select line SSL, the drain select line DSL, and the plurality of word lines WL. The plurality of pass transistors PT include active patterns that are respectively coupled to the conductive layers of the gate stack structure.

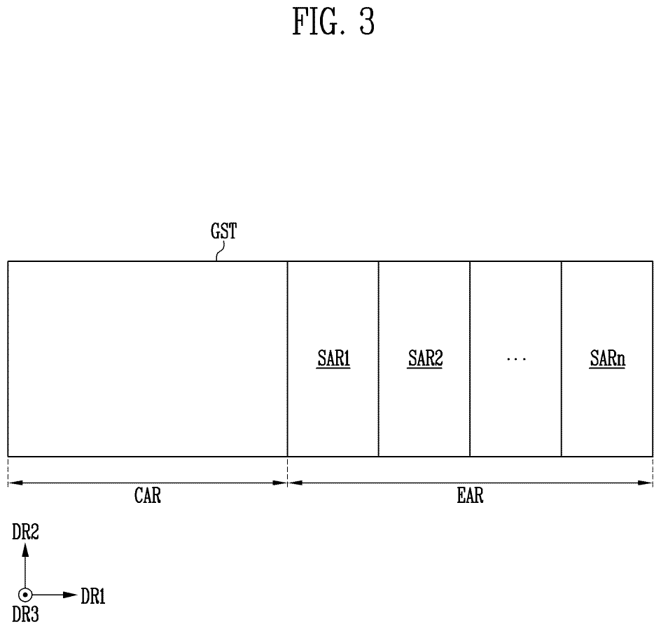

FIG. 3 is a diagram illustrating a gate stack structure GST of the memory cell array 10 according to an embodiment of the present disclosure.

Referring to FIG. 3, the gate stack structure GST includes a cell region CAR and an extension region EAR that is extended from the cell region CAR. The gate stack structure GST includes conductive layers and insulating layers that are extended in a horizontal direction. In an embodiment, the horizontal direction may correspond to a first direction DR1 or a second direction DR2. The first direction DR1 and the second direction DR2 shown in FIG. 3 are directions in which axes crossing each other face each other in a plane. The conductive layers and the insulating layers of the gate stack structure GST are alternately disposed in a vertical direction. A third direction DR3 shown in FIG. 3 is the vertical direction. In an embodiment, the first direction DR1, the second direction DR2, and the third direction DR3 may correspond to an X-axis direction, a Y-axis direction, and a Z-axis direction, respectively.

In an embodiment, the gate stack structure GST includes a plurality of stepped regions SAR1 to SARn disposed in the extension region EAR (n is a natural number of 2 or more). The plurality of pass transistors PT shown in FIG. 2 overlap with the plurality of stepped regions SAR1 to SARn of the gate stack structure GST.

The gate stack structure GST may have a stepped structure in each of the plurality of stepped regions SAR1 to SARn. The stepped structures disposed in different stepped regions are disposed at different levels.

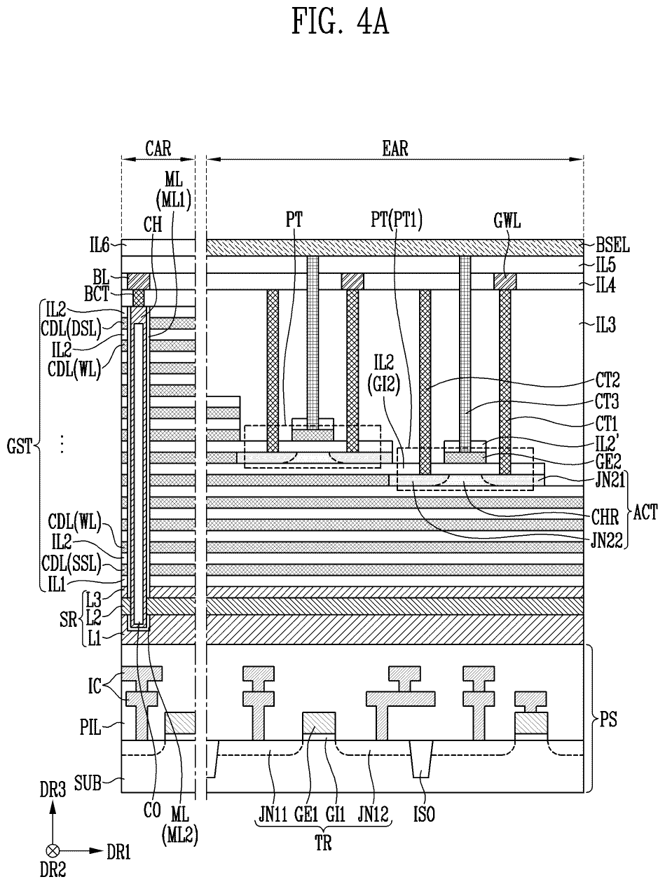

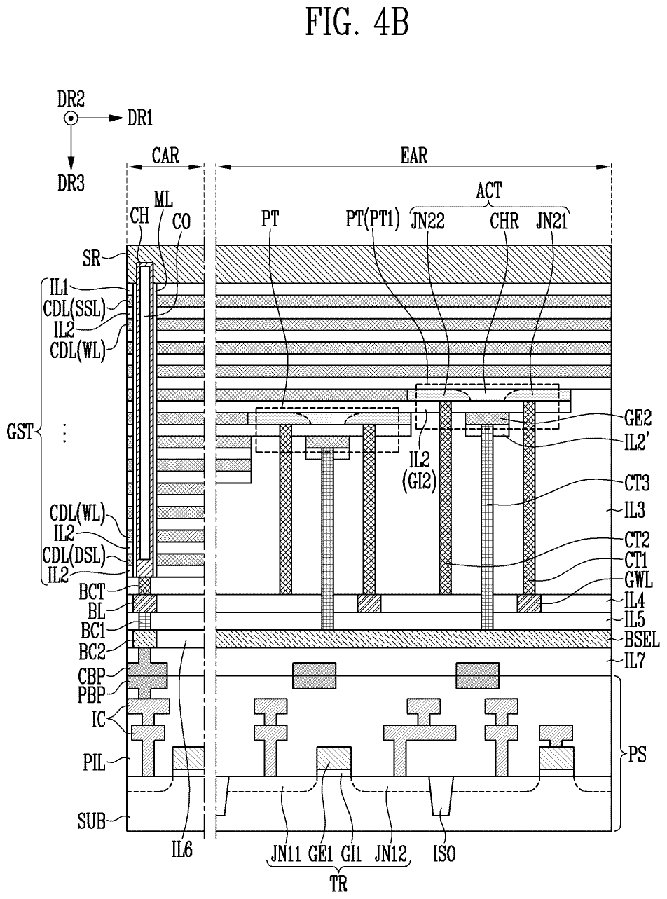

FIG. 4A and FIG. 4B are cross-sectional views illustrating a semiconductor memory device according to an embodiment of the present disclosure.

Referring to FIG. 4A and FIG. 4B, the semiconductor memory device includes the source layer SR, the bit line BL, the gate stack structure GST, a channel structure CH, a memory layer ML, the pass transistors PT, the global lines (for example, GWL), the block select line BSEL, and the peripheral circuit structure PS.

The source layer SR includes at least one layer of doped semiconductor layer. The source layer SR includes an N-type impurity as a majority carrier. A region that includes an N-type impurity as a majority carrier is provided as a source region.

Referring to FIG. 4A, the source layer SR may include a first doped semiconductor layer L1, a second doped semiconductor layer L2, and a third doped semiconductor layer L3 in an embodiment. One of the first doped semiconductor layer L1, the second doped semiconductor layer L2, and the third doped semiconductor layer L3 may include an N-type impurity as a majority carrier and the others may include an N-type impurity or a P-type impurity as a majority carrier. In an embodiment, the second doped semiconductor layer L2 may include an N-type impurity as a majority carrier and may be provided as a source region. The third doped semiconductor layer L3 may include an N-type impurity or a P-type impurity as a majority carrier. According to the embodiment in which the third doped semiconductor layer L3 includes the P-type impurity as the majority carrier, the third doped semiconductor layer L3 may be provided as a well region. The first doped semiconductor layer L1 may include an N-type impurity or a P-type impurity as a majority carrier.

Referring to FIG. 4B, the source layer SR may be formed as a single doped semiconductor layer in an embodiment. The single doped semiconductor layer may include a first conductivity-type doped region that includes an N-type impurity as a majority carrier. The single doped semiconductor layer may further include a second conductivity-type doped region that includes a P-type impurity as a majority carrier.

Referring to FIG. 4A and FIG. 4B, the source layer SR is extended in the first direction DR1 and the second direction DR2. The bit line BL is spaced apart from the source layer SR in the third direction DR3 and the length of the bit line BL is defined in the second direction DR2.

The gate stack structure GST includes insulating layers and conductive layers CDL that are disposed alternately between the source layer SR and the bit line BL. The insulating layers of the gate stack structure GST are divided into a first insulating layer IL1 and second insulating layers IL2. The first insulating layer IL1 is disposed adjacent to the source layer SR and includes the cell region CAR and the extension region EAR that is extended from the cell region CAR. The second insulating layers IL2 are disposed alternately with the conductive layers CDL in the third direction DR3 over the first insulating layer IL1. The first insulating layer IL1 and each of the second insulating layers IL2 include an insulating material such as a silicon oxide layer.

The conductive layers CDL of the gate stack structure GST are disposed over the first insulating layer IL1 and are spaced apart from each other in the third direction DR3. Each of the conductive layers CDL includes various conductive materials, such as a doped semiconductor layer, a metal layer, or the like. The doped semiconductor layer may include a doped silicon layer. The metal layer may include tungsten (W), copper (Cu), molybdenum (Mo), or the like. Each of the conductive layers CDL may further include a metal nitride layer that is provided as a barrier layer. The metal nitride layer may include titanium nitride (TIN), tantalum nitride (TaN), or the like.

The first insulating layer IL1 is penetrated by the channel structure CH in the cell region CAR. The channel structure CH serves as a channel region of the memory cell string CS shown in FIG. 2. The channel structure CH includes semiconductor materials such as silicon (Si), germanium (Ge), or a mixture thereof. The channel structure CH is extended in the third direction DR3 to penetrate the gate stack structure GST. In an embodiment, the channel structure CH has a tubular structure that is extended to a length in the third direction DR3. A core insulating layer CO is disposed in a central region defined by the tubular structure of the channel structure CH. The channel structure CH includes a capping portion. The capping portion of the channel structure CH forms one end of the channel structure CH facing the third direction DR3. The capping portion of the channel structure CH surrounds an end portion of the core insulating layer CO facing the bit line BL and includes at least one of an N-type impurity or a P-type impurity. In an embodiment, the capping portion of the channel structure CH may include an N-type impurity as a majority carrier.

The memory layer ML is extended along a side wall of the channel structure CH. The memory layer ML is interposed between the channel structure CH and the first insulating layer IL1. The memory layer ML is extended in the third direction DR3 to be interposed between each of the conductive layers CDL and the second insulating layers IL2, and the channel structure CH. The memory layer ML includes a blocking insulating layer between the gate stack structure GST and the channel structure CH, a data storage layer between the blocking insulating layer and the channel structure CH, and a tunnel insulating layer between the data storage layer and the channel structure CH. The tunnel insulating layer is extended along an outer wall of the channel structure CH and includes an insulating material such as a silicon oxide layer. The data storage layer is extended continuously along an outer wall of the tunnel insulating layer or is separated into data storage patterns that are spaced apart from each other in the third direction DR3. The data storage patterns respectively are disposed at levels in which the conductive layers CDL are disposed. The data storage layer may include a material layer capable of storing data that is changed using Fowler-Nordheim tunneling. In an embodiment, the data storage layer may include a charge trap insulating layer, a floating gate layer, or an insulating layer containing conductive nanodots. The charge trap insulating layer may include a silicon nitride layer. The blocking insulating layer may include at least one of a silicon dioxide (SiO₂) layer and a high dielectric layer that has a higher dielectric constant than a silicon dioxide (SiO₂) layer. The high dielectric layer may include an aluminum oxide layer, a hafnium oxide layer, or the like.

The channel structure CH includes a contact surface that is in contact with the source layer SR. The contact surface may be defined at a portion of the side wall of the channel structure CH, the other end of the channel structure CH, and so on. The other end of the channel structure CH faces the opposite direction of the capping portion described above.

Referring to FIG. 4A, in an embodiment, the memory layer ML may be penetrated by the second doped semiconductor layer L2 of the source layer SR and may be separated into a first memory layer ML1 and a second memory layer ML2. The second doped semiconductor layer L2 of the source layer SR contacts the portion of the side wall of the channel structure CH that is disposed between the first memory layer ML1 and the second memory layer ML2. Accordingly, the contact surface between the channel structure CH and the source layer SR is defined. The first memory layer ML1 is interposed between the gate stack structure GST and the channel structure CH, and is extended between the third doped semiconductor layer L3 of the source layer SR and the channel structure CH. The second memory layer ML2 is interposed between the first doped semiconductor layer L1 of the source layer SR and the channel structure CH.

Referring to FIG. 4B, in an embodiment, the source layer SR may include a groove. The other end of the channel structure CH protrudes farther into the source layer SR than the memory layer ML and is inserted in the groove of the source layer SR. The contact surface between the channel structure CH and the source layer SR is defined along the groove of the source layer SR.

Referring to FIG. 4A and FIG. 4B, the conductive layers CDL and the second insulating layers IL2 are disposed over the first insulating layer IL1. The conductive layers CDL and the second insulating layers IL2 are disposed alternately in the third direction DR3 along a side wall of the memory layer ML. The conductive layers CDL are spaced apart from each other in the third direction DR3 by the second insulating layers IL2. The conductive layers CDL and the second insulating layers IL2 surround the side wall of the memory layer ML over the cell region CAR of the first insulating layer IL1 and are extended over the extension region EAR of the first insulating layer IL1.

At least one layer of the conductive layers CDL which is adjacent to the first insulating layer IL1 serves as the source select line SSL, at least one layer of the conductive layers CDL which is adjacent to the bit line BL serves as the drain select line DSL, and the other conductive layers CDL serve as the word lines WL.

The second insulating layers IL2 have stepped structures in the plurality of stepped regions SAR1 to SARn shown in FIG. 3. The stepped structures in different stepped regions include the second insulating layers IL2 which are disposed at different levels. The second insulating layers IL2 are divided into a plurality of pairs and each pair includes two adjacent second insulating layers IL2 in the third direction DR3. Each pair of the second insulating layers IL2 is adjacent to each other in the third direction DR3 with a corresponding conductive layer, among the conductive layers CDL, interposed therebetween and protrudes farther in the horizontal direction than the corresponding conductive layer. In an embodiment, each pair of the second insulating layers IL2 protrudes farther in the first direction DR1 than the corresponding conductive layer.

Active patterns ACT are disposed between the second insulting layers IL2. Each of the active patterns ACT is disposed between consecutive second insulating layers of the second insulating layers IL2. In addition, each of the active patterns ACT is extended from a corresponding conductive layer among the conductive layers CDL. The active patterns ACT are disposed in a stepped structure over the extension region EAR of the first insulating layer IL1. Each of the active patterns ACT is coupled to a corresponding conductive layer that is disposed in the same layer. Gate electrodes GE2 respectively are disposed over the active patterns ACT and respectively overlap with the active patterns ACT. Each of the gate electrodes GE2 is spaced apart from the active pattern ACT with a gate insulating region GI2 of a corresponding second insulating layer, among the second insulating layers IL2, interposed therebetween.

Each of the active patterns ACT, a gate electrode GE2 a corresponding active pattern ACT, and the gate insulating region GI2 of the second insulating layer form the pass transistor PT. The gate electrode GE2 serves as a gate of the pass transistor PT and the gate insulating region GI2 of the second insulating layer serves as a gate insulating layer of the pass transistor PT. The gate electrode GE2 includes the same conductive material as the conductive layers CDL.

The active pattern ACT includes a doped semiconductor layer. In an embodiment, the active pattern ACT may include a P-type doped semiconductor layer such as a P-type doped silicon layer. The active pattern ACT includes a channel region CHR that overlaps with the gate electrode GE2. The channel region CHR of the active pattern ACT serves as a channel region of the pass transistor PT. The active pattern ACT includes a first junction JN21 and a second junction JN22 that are spaced apart from each other with the channel region CHR interposed therebetween. The first junction JN21 and the second junction JN22 are disposed at both sides of the channel region CHR. The first junction JN21 and the second junction JN22 serves as a source region and a drain region of the pass transistor PT. In an embodiment, the first junction JN21 and the second junction JN22 may include an N-type impurity as a majority carrier.

In an embodiment, a dummy pattern IL2′ may overlap with the gate electrode GE2. The dummy pattern IL2′ is disposed at the same layer as one of the second insulating layers IL2 and includes the same material as the second insulating layers IL2. However, embodiments of the present disclosure are not limited thereto and the dummy pattern IL2′ may be omitted.

The gate stack structure GST and the pass transistors PT are covered with a third insulating layer IL3. The third insulating layer IL3 is covered with a fourth insulating layer IL4. The bit line BL is formed in the fourth insulating layer IL4. The channel structure CH is electrically coupled to the bit line BL via a bit line contact structure BCT. The bit line contact structure BCT penetrates the third insulating layer IL3 and is coupled to the bit line BL and the channel structure CH.

Global lines such as the global word line GWL are formed in the fourth insulating layer IL4. Each of the global lines is electrically coupled to a corresponding pass transistor PT via a first contact plug CT1. The first contact plug CT1 penetrates the third insulating layer IL3 and is coupled to a corresponding global line and a corresponding first junction JN21.

The third insulating layer IL3 is penetrated by a second contact plug CT2 that is coupled to the second junction JN22. The second contact plug CT2 includes a contact surface that is in contact with the second junction JN22 and is extended in the third direction DR3 to penetrate the third insulating layer IL3. The third insulating layer IL3 and the fourth insulating layer IL4 block the remaining surfaces of the second contact plug CT2 except for the contact surface. In an embodiment, the second contact plug CT2 as described above serves as a dummy plug. In some embodiments, the second contact plug CT2 may be referred to as a dummy contact plug.

The global lines such as the global word line GWL and the bit line BL are covered with a fifth insulating layer IL5 and the fifth insulating layer IL5 is covered with a sixth insulating layer IL6. The block select line BSEL is disposed in the sixth insulating layer IL6. The block select line BSEL is electrically coupled to the gate electrodes GE2 via third contact plugs CT3. One block select line BSEL is coupled to the third contact plugs CT3 and controls the gate electrodes GE2 of the pass transistors PT.

Each of the third contact plugs CT3 is extended from a corresponding gate electrode GE2 to the block select line BSEL and penetrates the dummy pattern IL2′, the third insulating layer IL3, the fourth insulating layer IL4, and the fifth insulating layer IL5.

The peripheral circuit structure PS includes a plurality of transistors TR. In an embodiment, the plurality of transistors TR may include a transistor of the page buffer 37 shown in FIG. 1. Each of the transistors TR is disposed in an active region of a semiconductor substrate SUB partitioned by isolation layers ISO. Each of the transistors TR includes junctions JN11 and JN12, a gate insulating layer GI1, and a gate electrode GE1. The junctions JN11 and JN12 are disposed to be spaced apart from each other in the active region of the semiconductor substrate SUB. The gate insulating layer GI1 and the gate electrode GE1 are stacked over the active region between the junctions JN11 and JN12.

The plurality of transistors TR are covered with a peripheral insulating structure PIL disposed over the semiconductor substrate SUB. A plurality of interconnections IC are disposed in the peripheral insulating structure PIL. The plurality of interconnections IC includes at least one of a plurality of conductive lines and a plurality of conductive contacts for an electrical connection.

Referring to FIG. 4A, in an embodiment, the peripheral circuit structure PS may be disposed more adjacent to the source layer SR than the bit line BL. The source layer SR may be disposed between the peripheral insulating structure PIL and the gate stack structure GST.

Referring to FIG. 4B, in an embodiment, the peripheral circuit structure PS may be disposed more adjacent to the bit line BL than the source layer SR. The bit line BL may be disposed between the peripheral insulating structure PIL and the gate stack structure GST. The sixth insulating layer IL6 and the block select line BSEL are disposed between the bit line BL and the peripheral insulating structure PIL. A seventh insulating layer IL7 is interposed between the peripheral insulating structure PIL and each of the sixth insulating layer IL6 and the block select lines BSEL.

A plurality of cell side bonding patterns CBP are disposed in the seventh insulating layer IL7. A plurality of peripheral circuit side bonding patterns PBP corresponding to the plurality of cell side bonding patterns CBP are disposed in the peripheral insulating structure PIL. The plurality of cell side bonding patterns CBP are bonded to the plurality of peripheral circuit side bonding patterns PBP.

A portion of the plurality of cell side bonding patterns CBP may be electrically coupled to the bit line BL via at least one bit line connection structure. In an embodiment, a first cell side bonding pattern among the plurality of cell side bonding patterns CBP may be electrically coupled to the bit line BL via a first bit line connection structure BC1 and a second bit line connection structure BC2. The first bit line connection structure BC1 penetrates the fifth insulating layer IL5 and the second bit line connection structure BC2 penetrates the sixth insulating layer IL6.

A portion of the plurality of peripheral circuit side bonding patterns PBP may be electrically coupled to a transistor of a page buffer via the interconnection IC. A peripheral circuit side bonding pattern that is electrically coupled to the transistor of the page buffer may be bonded to a first cell side bonding pattern. Accordingly, the bit line BL may electrically be coupled to the page buffer via the first cell side bonding pattern and the peripheral circuit side bonding pattern.

Referring to FIG. 4A and FIG. 4B, in an embodiment, an area of the semiconductor substrate SUB which is allocated to the pass transistors PT may be reduced as the pass transistors PT are disposed between the peripheral circuit structure PS and the gate stack structure GST. In an embodiment, the active pattern ACT of each of the pass transistors PT is directly coupled to a corresponding conductive layer CDL, thereby reducing the bias loss between the pass transistor PT and the conductive layer CDL. Accordingly, in an embodiment, the operating characteristics of the semiconductor memory device, such as program efficiency, may be enhanced.

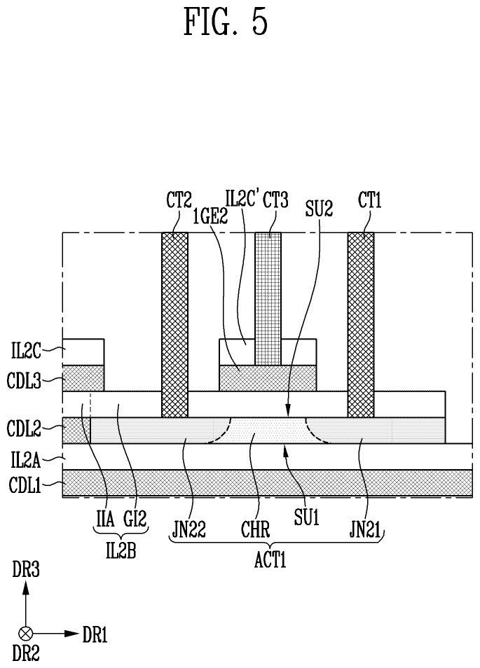

FIG. 5 is a cross-sectional view illustrating the pass transistor PT according to an embodiment of the present disclosure. FIG. 5 is an enlarged cross-sectional view of a first active pattern ACT1 and the surrounding components that form a first pass transistor PT1 among the pass transistors PT shown in FIG. 4A or 4B.

Referring to FIG. 5, the second insulating layers IL2 shown in FIG. 4A or 4B include a first intervening layer IL2A, a second intervening layer IL2B, and a third intervening layer IL2C that are sequentially stacked in the third direction DR3. The first intervening layer IL2A, the second intervening layer IL2B, and the third intervening layer IL2C have a stepped structure over the extension region EAR of the first insulating layer IL1 shown in FIG. 4A or 4B.

The conductive layers CDL shown in FIG. 4A or 4B includes a first conductive layer CDL1, a second conductive layer CDL2, and a third conductive layer CDL3 that are sequentially stacked in the third direction DR3. The second conductive layer CDL2 is coupled to the first active pattern ACT1. The third conductive layer CDL3 is a gate electrode level conductive layer disposed at the same level as a first gate electrode 1GE2. The first gate electrode 1GE2 is disposed over the first active pattern ACT1 and overlaps with the first active pattern ACT1.

The first conductive layer CDL1 includes an area that overlaps with the first active pattern ACT1 and protrudes farther in the horizontal direction than the first active pattern ACT1. In an embodiment, the first conductive layer CDL1 protrudes farther in the first direction DR1 than the first active pattern ACT1. In an embodiment, the horizontal direction is the first direction DR1.

The first intervening layer IL2A is disposed between the first conductive layer CDL1 and the second conductive layer CDL2. The first active pattern ACT1 includes a first surface SU1 and a second surface SU2 that are opposite to each other. The first surface SU1 faces the first insulating layer IL1 shown in FIG. 4A or 4B. The first intervening layer IL2A is extended along the first surface SU1 of the first active pattern ACT1. The first intervening layer IL2A protrudes farther in the horizontal direction than the first active pattern ACT1 to cover the first conductive layer CDL1. In an embodiment, the first intervening layer IL2A protrudes farther in the first direction DR1 than the first active pattern ACT1.

The first active pattern ACT1 is extended from the second conductive layer CDL2 and is disposed between the first intervening layer IL2A and the second intervening layer IL2B which are adjacent in the third direction DR3. The first junction JN21 of the first active pattern ACT1 is spaced apart from the second conductive layer CDL2 with the channel region CHR interposed therebetween. The second junction JN22 of the first active pattern ACT1 contacts the second conductive layer CDL2.

The second intervening layer IL2B is extended along the second surface SU2 of the first active pattern ACT1. The second intervening layer IL2B includes an interlayer insulating region IIA and a gate insulating region GI2. The interlayer insulating region IIA is interposed between the second conductive layer CDL2 and the third conductive layer CDL3. The gate insulating region GI2 is extended from the interlayer insulating region IIA to cover the second surface SU2 of the first active pattern ACT1. The gate insulating region GI2 is interposed between the first gate electrode 1GE2 and the first active pattern ACT1.

The third conducive layer CDL3 and the third intervening layer IL2C open the first active pattern ACT1. The third conducive layer CDL3 is disposed between the second intervening layer IL2B and the third intervening layer IL2C.

The first gate electrode 1GE2 is spaced apart from the third conductive layer CDL3 at the same level as the third conductive layer CDL3. The first gate electrode 1GE2 may be disposed between the second intervening layer IL2B and a dummy pattern IL2C′. The dummy pattern IL2C′ is disposed at the same level as the third intervening layer IL2C and includes the same material as the third intervening layer IL2C.

The first gate electrode 1GE2 is disposed between the first contact plug CT1 that is coupled to the first junction JN21 and the second contact plug CT2 that is coupled to the second junction JN22. The third contact plug CT3 that is coupled to the first gate electrode 1GE2 is disposed between the first contact plug CT1 and the second contact plug CT2. The second contact plug CT2, which is provided as a dummy plug, is extended in the third direction DR3 between the third conductive layer CDL3 and the first gate electrode 1GE2.

Hereinafter, a method of manufacturing a semiconductor memory device according to an embodiment of the present disclosure will be described which is mainly focused on a pass transistor and a memory cell array of the semiconductor memory device.

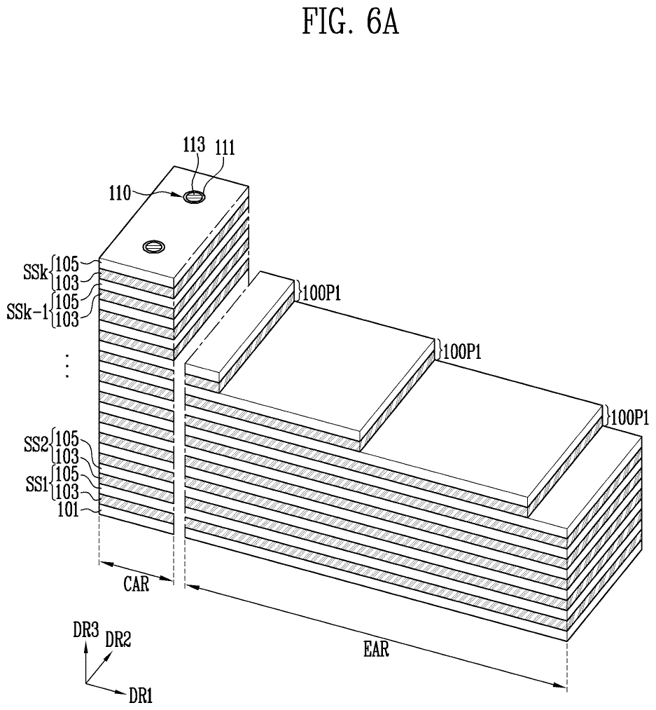

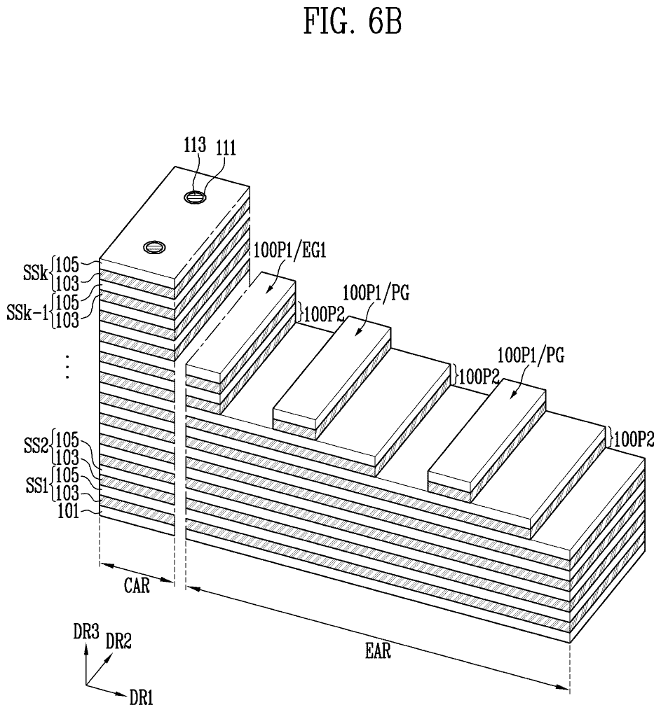

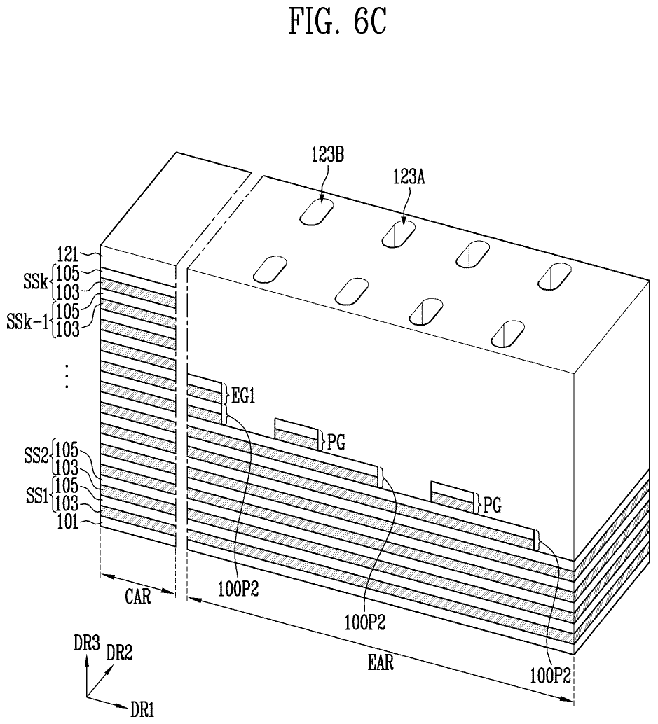

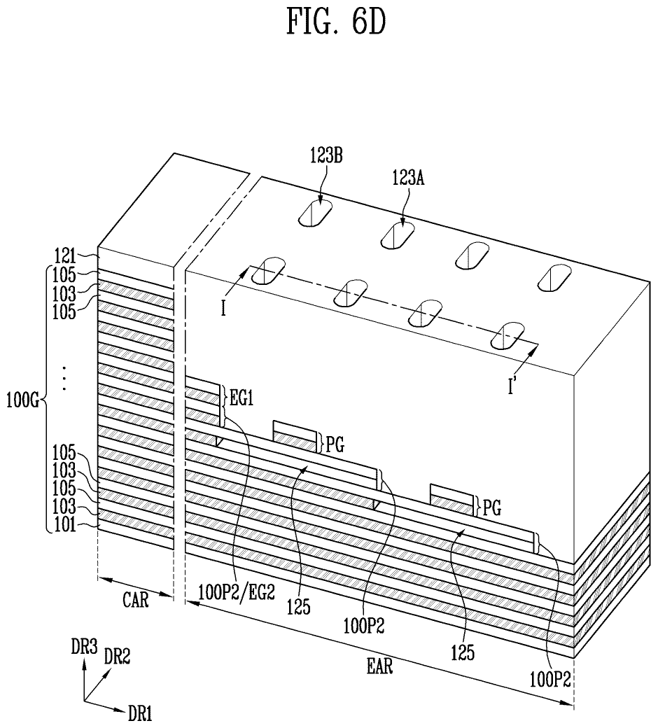

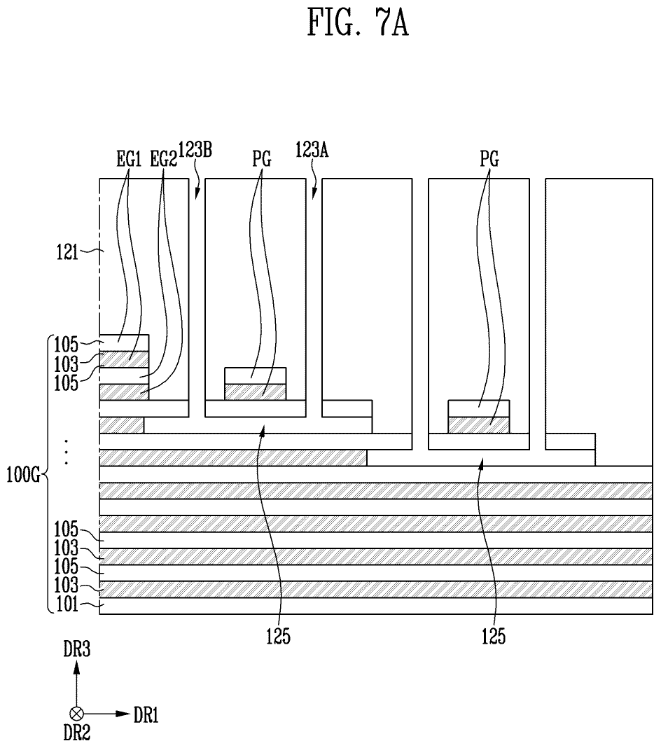

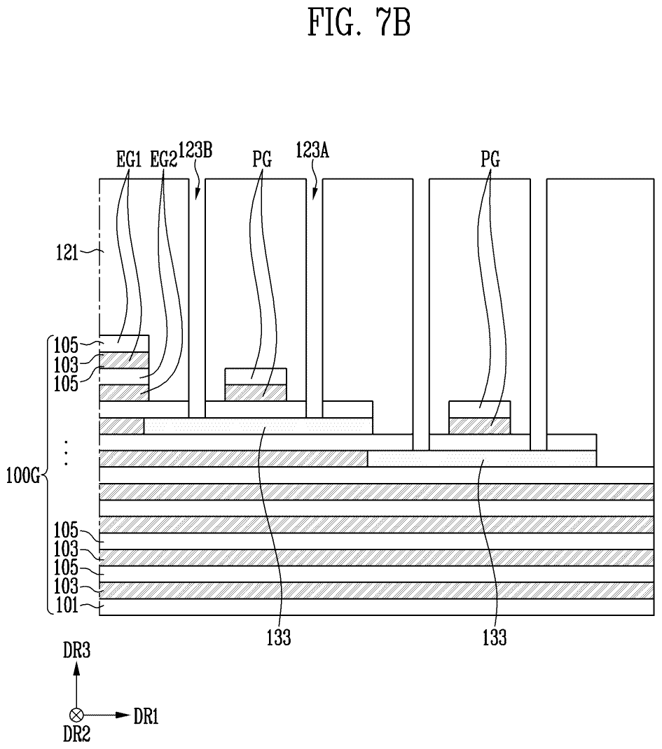

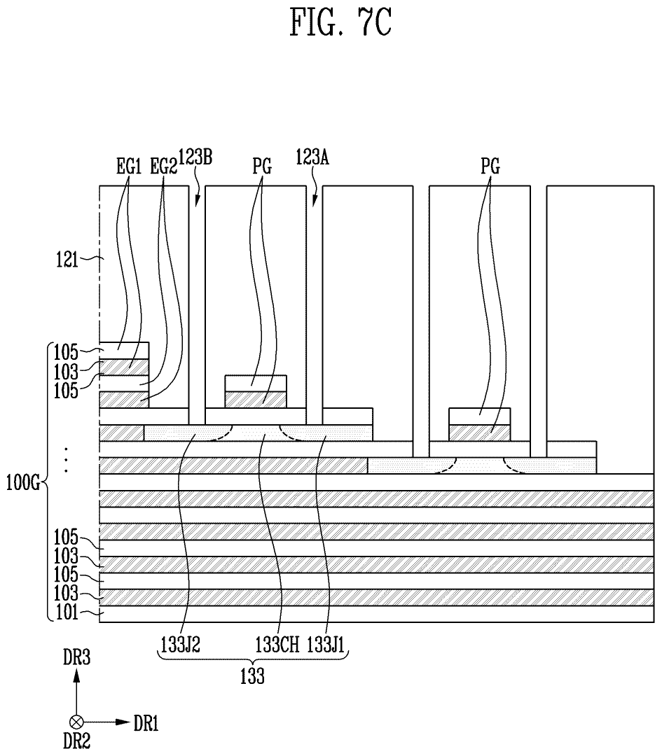

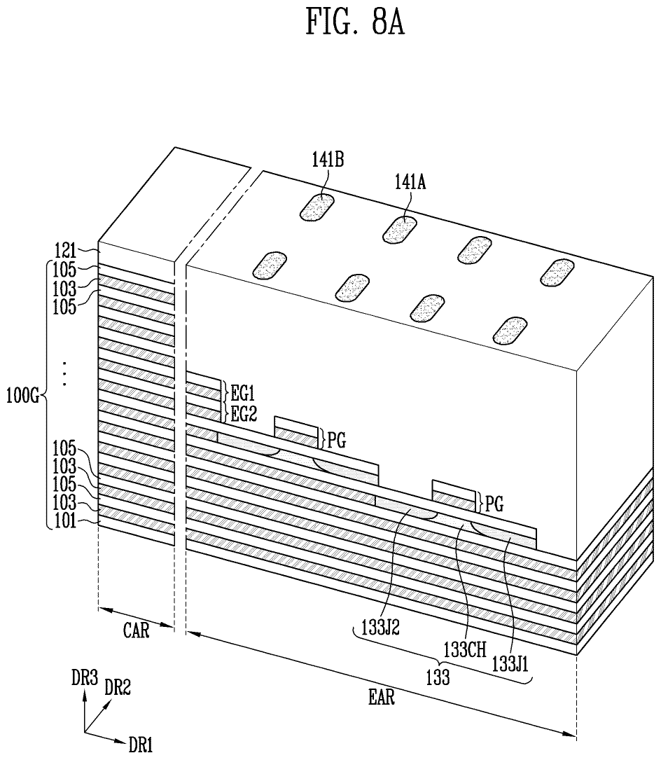

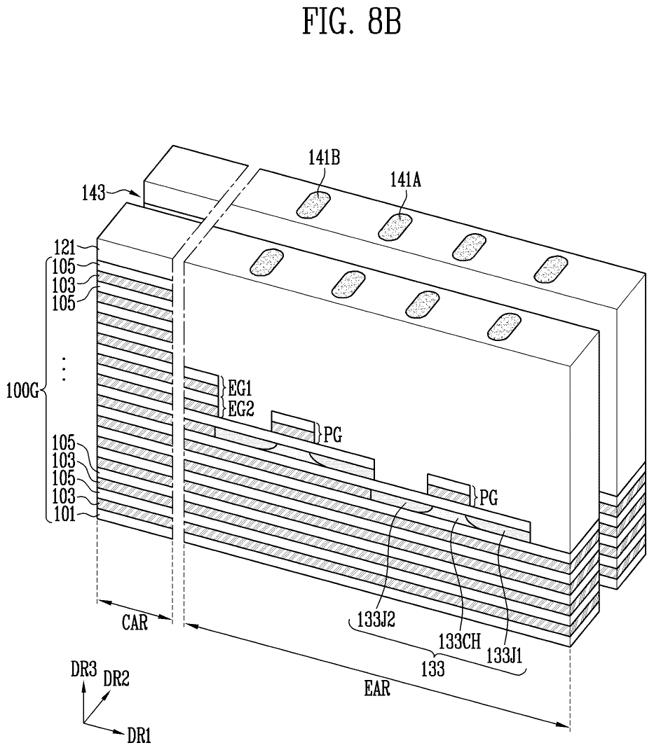

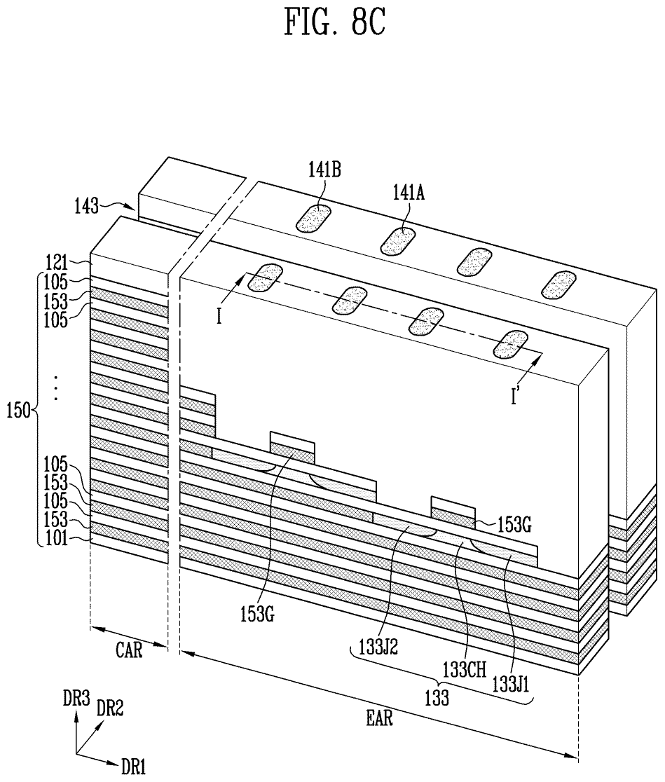

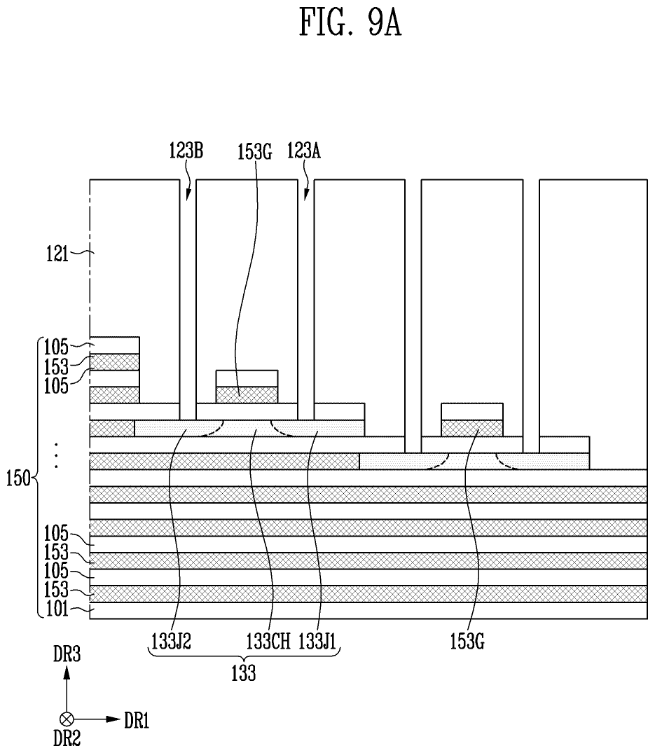

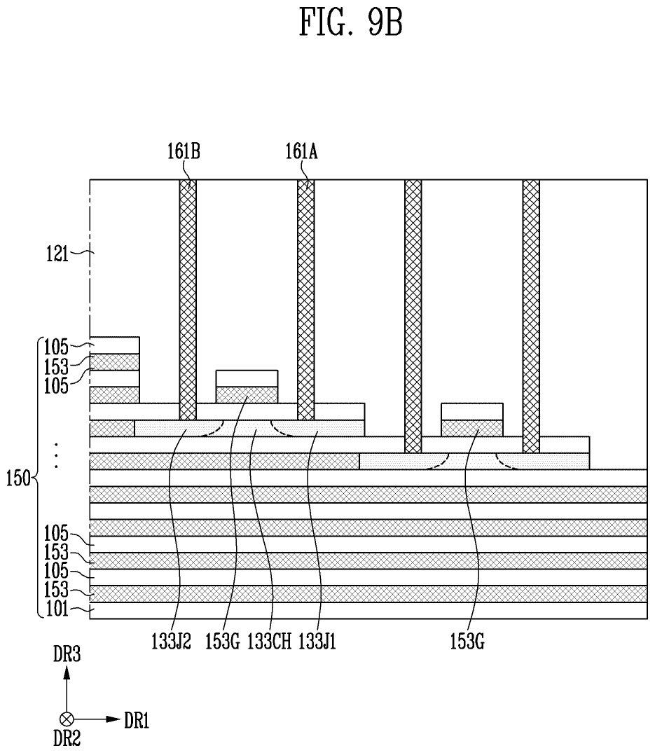

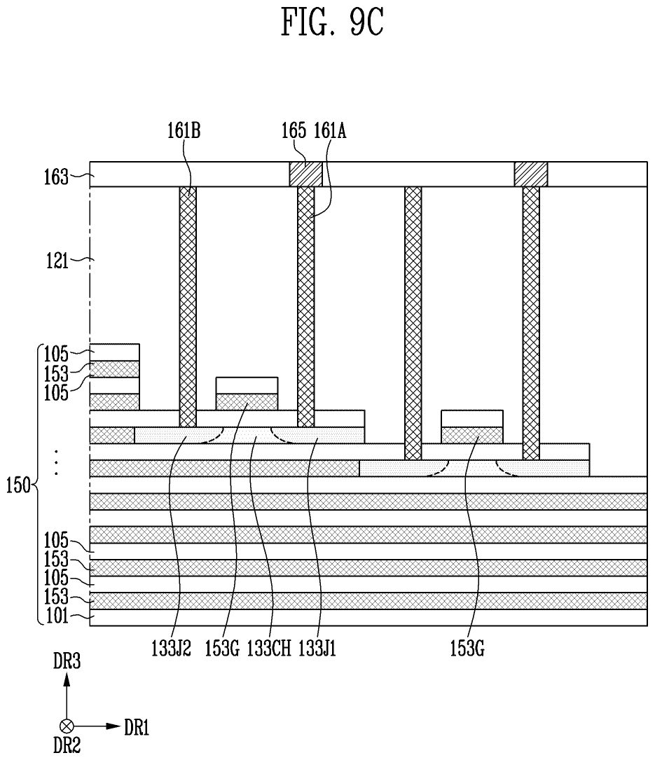

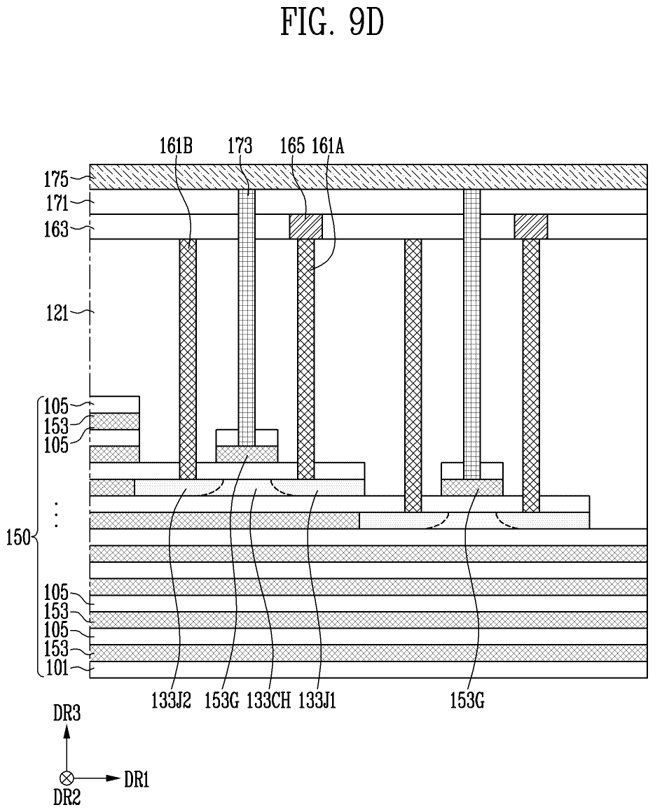

FIG. 6A to FIG. 6D, FIG. 7A to FIG. 7C, FIG. 8A to FIG. 8C, and FIG. 9A to FIG. 9D show manufacturing methods of a semiconductor memory device according to various embodiments of the present disclosure.

FIG. 6A to FIG. 6D are perspective views illustrating forming processes of a preliminary gate stack structure 100G, preliminary gate electrodes PG, and active openings 125.

Referring to FIG. 6A, a first insulating layer 101 is formed over a lower structure (not shown). Though not shown in FIG. 6A, in an embodiment, the lower structure may include the peripheral circuit structure PS shown in FIG. 4A and a preliminary source layer including the first doped semiconductor layer L1 shown in FIG. 4A, the third doped semiconductor layer L3 shown in FIG. 4A, and a sacrificial structure between the first doped semiconductor layer L1 and the third doped semiconductor layer L3. The sacrificial structure of the preliminary source layer may be replaced with the second doped semiconductor layer L2 shown in FIG. 4A in a subsequent process. In another embodiment, the lower structure may be a sacrificial substrate such as a silicon wafer. The sacrificial substrate may be replaced with the source layer SR shown in FIG. 4B in a subsequent process.

The first insulating layer 101 includes the cell region CAR and the extension region EAR that is extended from the cell region CAR. The first insulating layer 101 has a plate structure that is extended in the horizontal direction. The first direction DR1 and the second direction DR2 shown in FIG. 6A are directions in which axes crossing each other face each other in a plane. The plate structure of the first insulating layer 101 is extended in the first direction DR1 and the second direction DR2.

A plurality of sub-structures SS1 to SSk (k is a natural number of 2 or more) are disposed over the first insulating layer 101. The plurality of sub-structures SS1 to SSk are stacked in the vertical direction. The third direction DR3 shown in FIG. 6A is the vertical direction. In an embodiment, the first direction DR1, the second direction DR2, and the third direction DR3 may correspond to the X-axis direction, the Y-axis direction, and the Z-axis direction, respectively.

The plurality of sub-structures SS1 to SSk include sacrificial layers 103 and second insulating layers 105 that are alternately stacked in the third direction DR3. The sacrificial layers 103 and the second insulating layers 105 form a plurality of pairs and a stacked structure of the sacrificial layer 103 and the second insulating layer 105 of each pair form a corresponding sub-structure.

The sacrificial layers 103 include a material having an etch selectivity to the first insulating layer 101 and the second insulating layers 105. In an embodiment, the first insulating layer 101 and the second insulating layers 105 may include an insulating material such as a silicon oxide layer, a silicon oxynitride layer, and so forth. The sacrificial layers 103 may include a sacrificial insulating material such as a silicon nitride layer, and so forth.

Subsequently, a channel hole 110, which penetrates the cell region CAR of the first insulating layer 101 and the plurality of sub-structures SS1 to SSk over the cell region CAR, is formed. Subsequently, a memory layer 111 is formed along a side wall of the channel hole 110. Additionally, a channel structure 113 is formed in the channel hole 110 that is opened through the memory layer 111.

The plurality of sub-structures SS1 to SSk are etched to form a preliminary stepped structure over the extension region EAR of the first insulating layer 101. The preliminary stepped structure includes a plurality of first pad portions 100P1 of the plurality of sub-structures SS1 to SSk. Each of the first pad portions 100P1 has a stacked structure of a corresponding sacrificial layer 103 and a corresponding second insulating layer 105.

Referring to FIG. 6B, the plurality of sub-structures SS1 to SSk are etched to form a stepped structure and the preliminary gate electrodes PG over the extension region EAR of the first insulating layer 101.

The stepped structure includes a plurality of second pad portions 100P2 of the plurality of sub-structures SS1 to SSk. Each of the plurality of second pad portions 100P2 is formed by etching the sub-structure disposed under each of the plurality of first pad portions 100P1 shown in FIG. 6A. The plurality of second pad portions 100P2 respectively correspond to the plurality of first pad portions 100P1 shown in FIG. 6A.

Each of the preliminary gate electrodes PG is disposed over a portion of a corresponding second pad portion 100P2 among the plurality of second pad portions 100P2. The preliminary gate electrodes PG are formed by etching a portion of the plurality of first pad portions 100P1 shown in FIG. 6A. In other words, an etched first pad portion 100P1 forms each of the preliminary gate electrodes PG. The second pad portion 100P2 disposed under each of the preliminary gate electrodes PG includes regions that are opened at both sides of each preliminary gate electrode PG.

A portion of the plurality of first pad portions 100P1 may remain to form a first end portion EG1 of a corresponding sub-structure. The second pad portion 100P2 might not be opened under the first pad portion 100P1 forming the first end portion EG1 and may be covered with the first pad portion 100P1.

Referring to FIG. 6C, a third insulating layer 121 is formed over the plurality of sub-structures SS1 to SSk to cover the preliminary gate electrodes PG and the plurality of second pad portions 100P2.

Subsequently, a first opening 123A and a second opening 123B penetrating the third insulating layer 121 are formed. The first opening 123A and the second opening 123B are overlapped with some regions of the corresponding second pad portion 100P2 and expose the sacrificial layer 103 of the corresponding second pad portion 100P2.

Referring to FIG. 6D, the sacrificial layer 103 exposed through the first opening 123A and the second opening 123B is etched to form an active opening 125. The second pad portion 100P2 under the first pad portion 100P1 forming the first end portion EG1 remains to form a second end portion EG2 of a corresponding sub-structure.

A side wall of the first end portion EG1, a side wall of the second end portion EG2, and a side wall of the active opening 125 form a portion of side walls of the preliminary gate stack structure 100G. The preliminary gate stack structure 100G includes the first insulating layer 101 including the cell region CAR and the extension region EAR, and the sacrificial layers 103 and the second insulating layers 105 that are alternately stacked in the third direction DR3 over the first insulating layer 101. The sacrificial layers 103 and the second insulating layers 105 of the preliminary gate stack structure 100G are disposed over the cell region CAR of the first insulating layer 101 and are extended over the extension region EAR of the first insulating layer 101. A portion of the sacrificial layers 103 and the second insulating layers 105 form the first end portion EG1 and the second end portion EG2.

FIG. 7A to FIG. 7C each show a cross-section of the first insulating layer 101, the sacrificial layers 103, and the second insulating layers 105 of the preliminary gate stack structure 100G, the sacrificial layers 103 and the second insulating layers 105 of the preliminary gate electrodes PG, and the third insulating layer 121 which is taken along line I-I′ of FIG. 6D. FIG. 7A is a cross-sectional view of the structure shown in FIG. 6D. FIG. 7B and FIG. 7C are cross-sectional views illustrating processes that are performed after the process shown in FIG. 6D.

Referring to FIG. 6D and FIG. 7A, the first opening 123A and the second opening 123B penetrate the third insulating layer 121 and the second insulating layer 105 of the corresponding second pad portion 100P2 at both sides of a corresponding preliminary gate electrode PG.

The active opening 125 is overlapped with the preliminary gate electrode PG between the first opening 123A and the second opening 123B. The first opening 123A and the second opening 123B are coupled through the active opening 125. One side of the active opening 125 is defined along the sacrificial layer 103 that is disposed at the same level as the active opening 125 among the sacrificial layers 103 of the preliminary gate stack structure 100G. The other side of the active opening 125 is defined along the third insulating layer 121.

Referring to FIG. 7B, the active opening 125 shown in FIG. 7A is filled with an active pattern 133 through the first opening 123A and the second opening 123B. The active pattern 133 includes a doped semiconductor layer. In an embodiment, the active pattern 133 may include a P-type doped semiconductor layer such as a P-type doped silicon layer.

Referring to FIG. 7C, after the sacrificial layer 103 of the second pad portion 100P2 is replaced with the active pattern 133, a conductive impurity may be doped into both ends of the active pattern 133 through the first opening 123A and the second opening 123B. Accordingly, a first junction 133J1 and a second junction 13312 are respectively formed at the both ends of the active pattern 133. The first junction 133J1 is spaced apart from the preliminary gate stack structure 100G and the second junction 133J2 is in contact with the preliminary gate stack structure 100G.

A portion of the active pattern 133 between the first junction 133J1 and the second junction 13312 may serve as a channel region 133CH. In an embodiment where the channel region 133CH includes a P-type doped semiconductor layer, the first junction 133J1 and the second junction 13312 include an N-type impurity.

As described above, the first junction 133J1 and the second junction 13312 may be formed before the sacrificial layers 103 of the preliminary gate stack structure 100G and the sacrificial layers 103 of the preliminary gate electrodes PG are replaced with conductive materials. However, embodiments of the present disclosure are not limited thereto. In another embodiment, the first junction 133J1 and the second junction 13312 may be formed after a process that will be described below with reference to FIG. 9A.

FIG. 8A to FIG. 8C are perspective views illustrating forming processes of conductive layers 153 and gate electrodes 153G.

Referring to FIG. 8A, the first opening 123A and the second opening 123B shown in FIG. 7C are filled with a first sacrificial pillar 141A and a second sacrificial pillar 141B, respectively. The first sacrificial pillar 141A and the second sacrificial pillar 141B include a material having an etch selectivity to the first insulating layer 101, the second insulating layers 105, and the third insulating layer 121. In an embodiment, the first sacrificial pillar 141A and the second sacrificial pillar 141B may include a silicon nitride layer, an amorphous carbon layer, and so forth.

Referring to FIG. 8B, a slit 143 is formed to penetrate the third insulating layer 121, the preliminary gate stack structure 100G, and the preliminary gate electrodes PG. Side walls of the preliminary gate stack structure 100G and the preliminary gate electrodes PG are exposed through the slit 143. The slit 143 is extended in a direction crossing the preliminary gate electrodes PG and penetrates the active pattern 133.

Referring to FIG. 8C, after removing the sacrificial layers of the preliminary gate stack structure 100G and the sacrificial layers of the preliminary gate electrodes PG shown in FIG. 8B through the slit 143, regions where the sacrificial layers are removed are filled with a conductive material. The conductive material which replaces each of the sacrificial layers of the preliminary gate stack structure 100G and the preliminary gate electrodes PG is divided into the conductive layers 153 and the gate electrodes 153G.

The conductive layers 153 replace the sacrificial layers 103 of the preliminary gate stack structure 100G shown in FIG. 8B and are disposed alternately with the second insulating layers 105 in the third direction DR3 over the first insulating layer 101. The conductive layers 153 and the second insulating layers 105 are disposed over the cell region CAR of the first insulating layer 101 and are extended over the extension region EAR of the first insulating layer 101. The first insulating layer 101, the conductive layers 153, and the second insulating layers 105 form a gate stack structure 150. Each of the conductive layers 153 contacts the active pattern 133 that is disposed at the same level. Each of the conductive layers 153 contacts the second junction 13312 of the active pattern 133 and is spaced apart from the first junction 133J1 of the active pattern 133 with the channel region 133CH and the second junction 13312 of the active pattern 133 interposed therebetween.

The gate electrodes 153G replace the sacrificial layers 103 of the preliminary gate electrodes PG shown in FIG. 8B and respectively overlap with the active patterns 133.

According to an embodiment of the present disclosure, the conductive layers 153, the gate electrodes 153G, and the active patterns 133 are formed by replacing the sacrificial layers included in the stack structure of the sub-structures SS1 to SSk shown in FIG. 6A. Accordingly, the conductive layers 153, the gate electrodes 153G, and the active patterns 133 may be self-aligned.

FIG. 9A to FIG. 9D each show a cross-section of the gate stack structure 150, the gate electrodes 153G, the active patterns 133, and the third insulating layer 121 taken along line I-I′ of FIG. 8C. FIG. 9A to FIG. 9D are cross-sectional views illustrating processes that are performed after the process shown in FIG. 8C.

Referring to FIG. 9A, the first sacrificial pillar 141A and the second sacrificial pillar 141B shown in FIG. 8C are removed. Accordingly, the active pattern 133 is exposed through the first opening 123A and the second opening 123B. In an embodiment, when the first junction 133J1 and the second junction 13312 are formed before removing the first sacrificial pillar 141A and the second sacrificial pillar 141B shown in FIG. 8C, the first junction 133J1 and the second junction 13312 may be exposed through the first opening 123A and the second opening 123B. In another embodiment, the first junction 133J1 and the second junction 133J2 may be formed by removing the first sacrificial pillar 141A and the second sacrificial pillar 141B shown in FIG. 8C and then doping a conductive impurity into the active pattern 133 through the first opening 123A and the second opening 123B.

The first junction 133J1 is exposed through the first opening 123A and the second junction 133J2 is exposed through the second opening 123B.

Referring to FIG. 9B, a first contact plug 161A and a second contact plug 161B are formed respectively in the first opening 123A and the second opening 123B shown in FIG. 9A by filling the first opening 123A and the second opening 123B shown in FIG. 9A with a conductive material. The first contact plug 161A is in contact with the first junction 133J1 and the second contact plug 161B is in contact with the second junction 133J2.

Referring to FIG. 9C, a fourth insulating layer 163 is formed over the third insulating layer 121. Subsequently, a global line 165 is formed in the fourth insulating layer 163. The global line 165 is coupled to the first contact plug 161A. The second contact plug 161B is covered with the fourth insulating layer 163 and may be insulated from external signal lines such as the global line 165 by the fourth insulating layer 163.

Referring to FIG. 9D, a fifth insulating layer 171 is formed over the fourth insulating layer 163. Subsequently, a third contact plug 173 is formed to penetrate the third insulating layer 121, the fourth insulating layer 163, and the fifth insulating layer 171.

The third contact plug 173 is extended to contact the gate electrode 153G. Then, subsequent processes such as a process of forming a block select line 175 coupled to the third contact plug 173 may be performed.

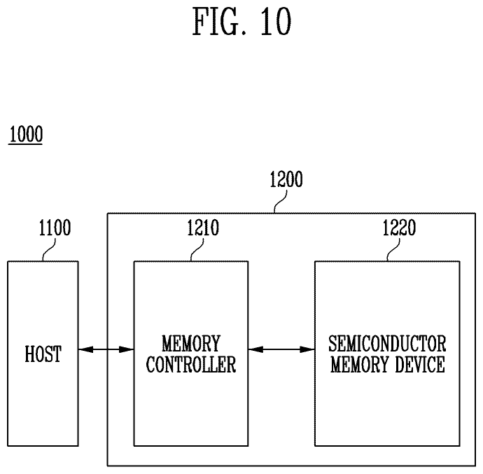

FIG. 10 is a block diagram illustrating an electronic system 1000 according to an embodiment of the present disclosure.

Referring to FIG. 10, the electronic system 1000 may be a computing system, a medical device, a communication device, a wearable device, a memory system, or the like. The electronic system 1000 may include a host 1100 and a storage device 1200.

The host 1100 may store data in the storage device 1200 or may read data stored in the storage device 1200 based on an interface. Examples of the interface may include at least one of Double Data Rate (DDR), Universal Serial Bus (USB), Multi-Media Card (MMC), embedded MMC (eMMC), Peripheral Component Interconnect (PCI), PCI-express (PCI-E), Advanced Technology Attachment (ATA), Serial-ATA (SATA), Parallel-ATA (PATA), Small Computer System Interface (SCSI), Enhanced Small Disk Interface (ESDI), Integrated Drive Electronics (IDE), Firewire, Universal Flash Storage (UFS), and Nonvolatile Memory express (NVMe) interfaces.

The storage device 1200 may include a memory controller 1210 and a semiconductor memory device 1220. In an embodiment, the storage device 1200 may be a storage medium such as a solid state drive (SSD) or a universal serial bus (USB) memory.

The memory controller 1210 may store data in the semiconductor memory device 1220 or read data stored in the semiconductor memory device 1220 in response to the control of the host 1100.

The semiconductor memory device 1220 may include one memory chip or a plurality of memory chips. The semiconductor memory device 1220 may store data or output stored data in response to the control of the memory controller 1210.

The semiconductor memory device 1220 may be a non-volatile memory device. As described above with reference to FIG. 4A or 4B, the semiconductor memory device 1220, in an embodiment, may include a first insulating layer, a channel structure penetrating the first insulating layer and extended in the vertical direction, a memory layer extended along a side wall of the channel structure, conductive layers disposed to be spaced apart from each other in the vertical direction along a side wall of the memory layer over the first insulating layer, an active pattern coupled to a corresponding conductive layer among the conductive layers, and a gate electrode disposed over the active pattern.

According to an embodiment of the present disclosure, an active pattern and a gate electrode disposed over the active pattern may serve as a pass transistor and the active pattern may be directly coupled to a conductive layer of a gate stack structure including an insulating layer and the conductive layer which are stacked alternately. Accordingly, in an embodiment, the connection structure between the conductive layer and the pass transistor may be simplified and the loss of a bias transferred from the pass transistor to the conductive layer may be reduced, thereby improving the operational reliability of a semiconductor memory device.

According to an embodiment of the present disclosure, an area where the active pattern and the gate electrode of the pass transistor are disposed is provided by etching a stacked structure of sub-structures, thereby improving the arrangement efficiency of the pass transistor.

What is claimed is:

1. A semiconductor memory device, comprising:
a first insulating layer including a cell region and an extension region, the extension region extended from the cell region;
a channel structure penetrating the first insulating layer in the cell region, the channel structure extending in a vertical direction;
a memory layer extending along a side wall of the channel structure;
conductive layers disposed to be spaced apart in the vertical direction along a side wall of the memory layer over the first insulating layer;
second insulating layers alternately disposed with the conductive layers in the vertical direction and extended over the extension region of the first insulating layer;
an active pattern disposed between adjacent second insulating layers in the vertical direction among the second insulating layers and coupled to a corresponding conductive layer among the conductive layers; and
a gate electrode disposed over the active pattern.

2. The semiconductor memory device of claim 1, wherein the adjacent second insulating layers in the vertical direction include a first intervening layer and a second intervening layer, the first intervening layer and the second intervening layer forming a stepped structure over the extension region of the first insulating layer,
wherein the first intervening layer is extended along a first surface of the active pattern, the first surface facing the first insulating layer, and
wherein the second intervening layer is extended along a second surface of the active pattern opposite to the first surface, the second intervening layer interposed between the active pattern and the gate electrode.

3. The semiconductor memory device of claim 1, further comprising a first junction and a second junction included in the active pattern, the first junction spaced apart from the second junction,
wherein the gate electrode is disposed over a region of the active pattern between the first junction and the second junction.

4. The semiconductor memory device of claim 3,
wherein the active pattern includes a P-type doped semiconductor layer, and
wherein each of the first junction and the second junction include an N-type impurity.

5. The semiconductor memory device of claim 3,
wherein the first junction is spaced apart from the corresponding conductive layer, and
wherein the second junction is in contact with the corresponding conductive layer.

6. The semiconductor memory device of claim 5, further comprising:
a contact plug extended in the vertical direction from the first junction; and
a global line coupled to the contact plug.

7. The semiconductor memory device of claim 5, further comprising a dummy contact plug extended in the vertical direction from the second junction.

8. The semiconductor memory device of claim 7,
wherein the conductive layers include a gate electrode level conductive layer disposed at a same level as the gate electrode, and
wherein the dummy contact plug is disposed between the gate electrode level conductive layer and the gate electrode.

9. The semiconductor memory device of claim 1, further comprising:
a contact plug extended in the vertical direction from the gate electrode; and
a block select line coupled to the contact plug.

10. A semiconductor memory device, comprising:
a first insulating layer including a cell region and an extension region, the extension region extended from the cell region;
a channel structure penetrating the first insulating layer in the cell region, the channel structure extending in a vertical direction;
a memory layer extending along a side wall of the channel structure;
conductive layers and second insulating layers disposed over the first insulating layer and alternately stacked along a side wall of the memory layer;
active patterns respectively extended from the conductive layers and disposed in a stepped structure over the extension region of the first insulating layer; and
gate electrodes respectively disposed over the active patterns.

11. The semiconductor memory device of claim 10,
wherein each of the active patterns includes a channel region overlapping a corresponding gate electrode among the gate electrodes and a first junction and a second junction disposed, respectively, at both sides of the channel region,
wherein the first junction is spaced apart from a corresponding conductive layer among the conductive layers, and
wherein the second junction is disposed between the corresponding conductive layer and the channel region, the second junction being in contact with the corresponding conductive layer.

12. The semiconductor memory device of claim 11,
wherein each of the active patterns includes a P-type doped semiconductor layer, and
wherein each of the first junction and the second junction includes an N-type impurity.

13. The semiconductor memory device of claim 10,
wherein the conductive layers include a first conductive layer, a second conductive layer, and a third conductive layer sequentially disposed in the vertical direction,
wherein the second insulating layers include a first intervening layer between the first conductive layer and the second conductive layer and a second intervening layer between the second conductive layer and the third conductive layer,
wherein the active patterns include a first active pattern extended from the second conductive layer, and
wherein the gate electrodes include a first gate electrode disposed over the first active pattern.

14. The semiconductor memory device of claim 13,
wherein the first conductive layer is extended to be disposed over the first active pattern,
wherein the first intervening layer is extended between the first conductive layer and the first active pattern,
wherein the second intervening layer includes an interlayer insulating region between the second conductive layer and the third conductive layer and a gate insulating region extended from the interlayer insulating region to cover the first active pattern, and
wherein the gate insulating region of the second intervening layer is interposed between the first gate electrode and the first active pattern.

15. The semiconductor memory device of claim 13,
wherein the first gate electrode is disposed at a same level as the third conductive layer.

16. The semiconductor memory device of claim 10, further comprising a first contact plug and a second contact plug coupled to each of the active patterns at both sides of each of the gate electrodes, respectively,
wherein each of the active patterns includes:
a first junction coupled to the first contact plug; and
a second junction coupled to a corresponding conductive layer among the conductive layers and the second contact plug, the second junction spaced apart from the first junction.

17. The semiconductor memory device of claim 16, further comprising:
a global line coupled to the first contact plug; and
at least one insulating layer surrounding the second contact plug,
wherein the second contact plug includes a contact surface contacting the second junction, and
wherein the at least one insulating layer surrounds other surfaces of the second contact plug except for the contact surface of the second contact plug contacting the second junction.

18. The semiconductor memory device of claim 10, further comprising:
contact plugs extended from the gate electrodes, respectively, in the vertical direction; and
a block select line coupled to the contact plugs.

19. A method of manufacturing a semiconductor memory device, the method comprising:
forming a first insulating layer including a cell region and an extension region, the extension region extended from the cell region;
stacking sub-structures over the first insulating layer, wherein each of the sub-structures is a stacked structure of a sacrificial layer and a second insulating layer;
forming a stepped structure and a preliminary gate electrode by etching the sub-structures, wherein the stepped structure is disposed over the extension region of the first insulating layer and the preliminary gate electrode is disposed over the stepped structure and includes a portion of the sacrificial layer;
forming a third insulating layer over the sub-structures to cover the stepped structure and the preliminary gate electrode;
forming a first opening and a second opening overlapping the stepped structure, respectively, at both sides of the preliminary gate electrode and penetrating the third insulating layer;
replacing a portion of the sacrificial layer of the stepped structure with an active pattern through the first opening and the second opening;
replacing the sacrificial layer with a conductive material; and
forming a first contact plug and a second contact plug in the first opening and the second opening, respectively.

20. The method of claim 19, wherein the forming of the stepped structure and the preliminary gate electrode comprises:
forming a preliminary stepped structure having first pad portions of the sub-structures by etching the sub-structures;
forming the stepped structure having second pad portions of the sub-structures by etching the sub-structures under the first pad portions; and
forming the preliminary gate electrode by etching at least one of the first pad portions, wherein the preliminary gate electrode includes an etched first pad portion and is disposed over a corresponding second pad portion among the second pad portions.

21. The method of claim 19,
wherein the conductive material is divided into a gate electrode which replaces the portion of the sacrificial layer of the preliminary gate electrode and a conductive layer which is disposed alternately with the second insulating layer over the cell region of the first insulating layer, and
wherein the conductive layer is extended to contact the active pattern at a level in which the active pattern is disposed.

22. The method of claim 21, further comprising forming a first junction and a second junction at both ends of the active pattern, respectively, by doping a conductive impurity through the first opening and the second opening,
wherein the first junction is spaced apart from the conductive layer and the second junction is in contact with the conductive layer at the level in which the active pattern is disposed.

23. The method of claim 22,
wherein the active pattern includes a P-type doped semiconductor layer, and
wherein each of the first junction and the second junction includes an N-type impurity.

24. The method of claim 22,
wherein the first contact plug is in contact with the first junction, and
wherein the second contact plug is in contact with the second junction.

25. The method of claim 24, further comprising:
forming at least one insulating layer over the third insulating layer to cover the first contact plug and the second contact plug; and
forming a global line penetrating the at least one insulating layer to be coupled to the first contact plug.

26. The method of claim 19, wherein the replacing of the sacrificial layer with the conductive material comprises:
filling each of the first opening and the second opening with a sacrificial pillar;
forming a slit penetrating the third insulating layer and the sub-structures and extended in a direction crossing the preliminary gate electrode;
removing the sacrificial layer through the silt; and
filling an area where the sacrificial layer is removed with the conductive material, and
wherein the method further comprises removing the sacrificial pillar before forming the first contact plug and the second contact plug.

27. The method of claim 19, further comprising:
forming a channel hole penetrating the first insulating layer in the cell region, the channel hole extended to penetrate the sub-structures;
forming a memory layer on a side wall of the channel hole; and
forming a channel structure in the channel hole opened through the memory layer.
